(19) United States
(12) Patent Application Publication
(10) Pub. No.: US 2014/0306027 A1
(43) Pub. Date: Oct. 16, 2014

(54) SHOWERHEAD OF A MOCVD REACTOR WITH LARGE DIAMETER

(71) Applicants: Xiaoming Xu, Hangzhou (CN); Yongjun Zhou, Hangzhou (CN); Jianwei Wu, Hangzhou (CN); Yunxin Ding, Hangzhou (CN)

(72) Inventors: Xiaoming Xu, Hangzhou (CN); Yongjun Zhou, Hangzhou (CN); Jianwei Wu, Hangzhou (CN); Yunxin Ding, Hangzhou (CN)

(73) Assignee: HANGZHOU SILAN AZURE CO., LTD, Hangzhou, Zhejiang (CN)

(21) Appl. No.: 14/240,927

(22) PCT Filed: Aug. 24, 2012
(86) PCT No.: PCT/CN2012/080564

§ 371 Date: May 20, 2014

(30) Foreign Application Priority Data
Aug. 26, 2011 (CN) 201110249030.2

(51) Int. Cl. C23C 16/455

(52) U.S. Cl. CPC C23C 16/45572; C23C 16/45565
USPC 239/132.3

(57) ABSTRACT

The present invention intends to provide a shower of a large diameter MOCVD reactor, and the difficulty for manufacturing the shower does not obviously increase when its size increases. The shower of a large diameter MOCVD reactor of the present invention comprises III group chamber, V group chamber and a cooling water chamber, and it is characterized in that, III group chamber, V group chamber and cooling water chamber are all separated as N chambers, wherein N is a natural number greater than or equal to 2 and each chamber is an individual unity.

### FIELD OF THE INVENTION

The present invention relates to a showerhead apparatus for delivering gas, and in particular, to a showerhead of a MOCVD reactor including a group-III chamber for circulating group-III gas, a group-V chamber for circulating group-V gas and a cooling water chamber for circulating cooling water.

### BACKGROUND

MOCVD, the English abbreviation of Metal-organic Chemical Vapor Deposition, refers to an unbalanced growing technique. Relying on the vapor transportation of the precursor and the subsequent reaction of a group-III alkyl compound and a group-V hydride in a heated region, it provides growth gas and dopants for a reactor and deposits them on the surface of the substrate.

A conventional showerhead used in a MOCVD reactor, such as the one provided by Thomas Swan Scientific Equipment Limited, has a sandwich structure with three chambers. The group-III gas flows into the reaction chamber body through a distribution conduit and a group-III chamber. The group-V gas flows into the reaction chamber body through a group-V chamber. The lowest layer is a cooling water chamber.

With the rapid growth and the fierce competition of the LED industry, the market is eager for a high throughput of MOCVD. The core of the MOCVD is the reactor. A rapid and effective way for enhancing the throughput is to enlarge the diameter of the reactor. Purely enlarging the diameter of the conventional showerhead may result in several issues below.

First, there will be an increase in the complexity in fabrication and manufacture of the showerhead and a decrease in the yield rate accordingly.

Second, it will be more difficult to cool the showerhead.

Third, the concentration distribution of the group-III gas along radial direction may face more challenges.

### SUMMARY

The present invention is directed to a showerhead of a MOCVD reactor with a large diameter. Even if the diameter of the showerhead is increased, there will not be a remarkable increase in the complexity in manufacturing.

To achieve the goal, a showerhead of a MOCVD reactor with a large diameter comprises a group-III chamber, a group-V chamber and a cooling water chamber. The showerhead is characterized in that the group-III chamber, the group-V chamber and the cooling water chamber each is divided into N chamber bodies, wherein N is a natural number greater than or equal to 2, and each chamber body is an independent chamber body.

Since the group-III chamber, the group-V chamber and the cooling water chamber each is divided into at least two independent chamber bodies, the fabrication area of a single piece is greatly reduced. Even if the showerhead has a large diameter, there will not be a remarkable increase in the complexity in fabrication and manufacturing of the showerhead. Moreover, since the group-III chamber, the group-V chamber and the cooling water chamber each is divided into at least two chamber bodies, if some of the chamber bodies are leaking during usage, only the chamber bodies which are leaking need to be replaced and there is no need to replace the entire showerhead, thereby ensuring convenient maintenance and lowering the maintenance cost.

The showerhead is further characterized in that a water inlet member in each chamber body of the cooling water chamber is disposed in an inner center of each chamber body and a water outlet member is disposed in a circumferential position of each chamber body.

The cooling water enters from the inner center and exits at the circumference. Thus, the path where the cooling water flows is shortened, which improves the cooling effect.

The showerhead is further characterized in that a group-V gas conduit to a reaction chamber below the showerhead is provided in the middle of the showerhead.

The group-V gas conduit in the middle of the showerhead may improve the concentration distribution of the group-V gas and enhance the flowing status of the gas.

The showerhead is further characterized in that each chamber body in the group-III chamber is divided into an upper chamber and a lower chamber by a distribution orifice plate, and the upper chamber and the lower chamber are interconnected with each other via the holes on the distribution orifice plate.

The group-III chamber is divided into the upper chamber and the lower chamber by the distribution orifice plate. Due to the variant arrangement of the holes on the distribution orifice plate, the concentration distribution of the group-III gas along the radial direction can be changed.

The showerhead is further characterized in that the N chambers are four equally divided chamber bodies.

The size of the four equally divided chamber bodies is reduced greatly compared to the size of a single chamber. Even if the diameter of the MOCVD reactor is increased, there will not be a remarkable increase in the complexity in fabrication and manufacturing of the showerhead.

The showerhead is further characterized in that the group-III chamber, the group-V chamber and the cooling water chamber are in a round shape. Each of the chamber bodies is in a fan shape.

The showerhead is further characterized in comprising a top assembly and a showering assembly, wherein the top assembly comprises an upper cover plate for providing the group-III chamber. A group-III gas inlet is formed on the upper cover plate. The group-III gas inlet is interconnected with the upper chamber of the group-III chamber. The showering assembly comprises N showering units. Each showering unit comprises an upper orifice plate, a middle orifice plate, a lower orifice plate, an enclosure sidewall, an upper capillary group and a lower capillary group. The upper orifice plate, the middle orifice plate and the enclosure sidewall between the upper orifice plate and the middle orifice plate form a chamber body of the group-V chamber. The group-V gas inlet leading to the chamber body of the group-V chamber is formed on the enclosure sidewall. The middle orifice plate, the lower orifice plate and the enclosure between the middle orifice plate and the lower orifice plate form a chamber body of the cooling water chamber. Capillaries in the upper capillary group are disposed through holes in the upper orifice plate, the middle orifice plate and the lower orifice plate. Capillaries in the lower capillary group are disposed through holes in the middle orifice plate and the lower orifice plate. The group-V chamber and the cooling water chamber cannot be communicated with each other. The lower capillary group links the group-V chamber with the reaction chamber below the showerhead. The showering assembly is disposed below the top assembly and each capillary of the upper capillary group links the group-III chamber with the reaction chamber below the showerhead; the upper capillary group and the lower capillary group are positioned in an interleaving manner.

The showerhead is further characterized in that the external of the showering assembly is surrounded by a cooling water ring.

The showerhead is characterized in further comprising a distribution conduit for distributing cooling water, wherein a water inlet member in each chamber body of the cooling water chamber is disposed in an inner center of each chamber body and a water outlet member is disposed at the circumference of each chamber body; each water inlet member is coupled to the same distribution conduit through a water inlet.

In some other features of the showerhead, the showering unit of the showering assembly as well as the distribution orifice plate of the top assembly consists of equally divided portions. This reduces the manufacturing area of a single piece greatly. Therefore, even if in the case of the MOCVD reactor with a large diameter, there will not be a remarkable increase in the complexity in the fabrication and manufacturing. Moreover, the cooling process is also conducted on the four equally divided portions. The cooling of the showerhead is no big issue. Because the process is conducted on the equally divided four portions, the group-III gas and the group-V gas can be mixed uniformly. Moreover, the inner diameter of the holes and the distance between the holes in each orifice plate can be properly increased so that the difficulty in fabrication and manufacturing is reduced and the yield rate is increased.

The foregoing features and advantages of the present invention will be illustrated with examples below in conjunction with the drawings.

### BRIEF DESCRIPTION OF THE DRAWINGS

Features, characteristics of the present disclosure will become apparent from the following embodiments when taken in conjunction with the drawings, in which:

FIG. 1 illustrates an exploded view of a showerhead according to the present invention;

FIG. 2 illustrates an axonometric view of a showerhead according to the present invention;

FIG. 3 illustrates a front view of a showerhead according to the present invention;

FIG. 4 illustrates a top view of a showerhead according to the present invention;

FIG. 5 illustrates an elevation view of a showerhead according to the present invention;

FIG. 6 is an A-A cross-section view of FIG. 5.

FIG. 7 is an enlarged view of part B in FIG. 6;

FIG. 8 is an enlarged view of part C in FIG. 6;

FIG. 9 illustrates an exploded view of a top assembly of a showerhead according to the present invention;

FIG. 10 illustrates an axonometric view of a top assembly of a showerhead according to the present invention;

FIG. 11 is an elevation view of FIG. 10;

FIG. 12 is an A-A cross-section view of FIG. 11;

FIG. 13 is an enlarged view of part D in FIG. 12;

FIG. 14 illustrates an axonometric view of a cooling water ring of a showerhead according to the present invention;

FIG. 15 is a top view of FIG. 14;

FIG. 16 illustrates an exploded view of a showering assembly of a showerhead according to the present invention;

FIG. 17 illustrates an axonometric view of a showering assembly of a showerhead according to the present invention;

FIG. 18 is a top view of FIG. 17;

FIG. 19 is an A-A cross-section view of FIG. 18;

FIG. 20 is an enlarged view of part B in FIG. 19;

FIG. 21 is a top view of FIG. 17;

FIG. 22 is a B-B cross-section view of FIG. 20;

FIG. 23 is a top view of FIG. 10;

FIG. 24 is a C-C cross-section view of FIG. 23;

FIG. 25 is an enlarged view of part D in FIG. 24.

### DETAILED DESCRIPTION

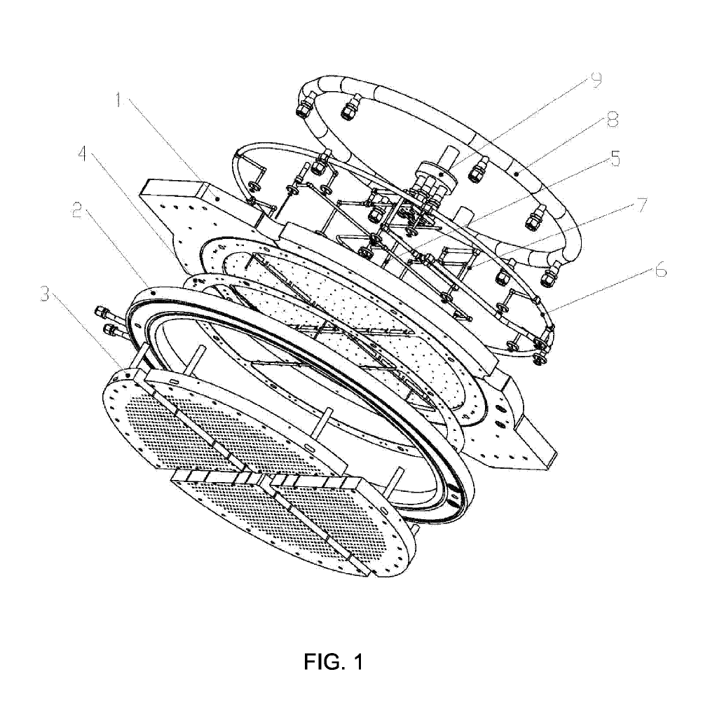

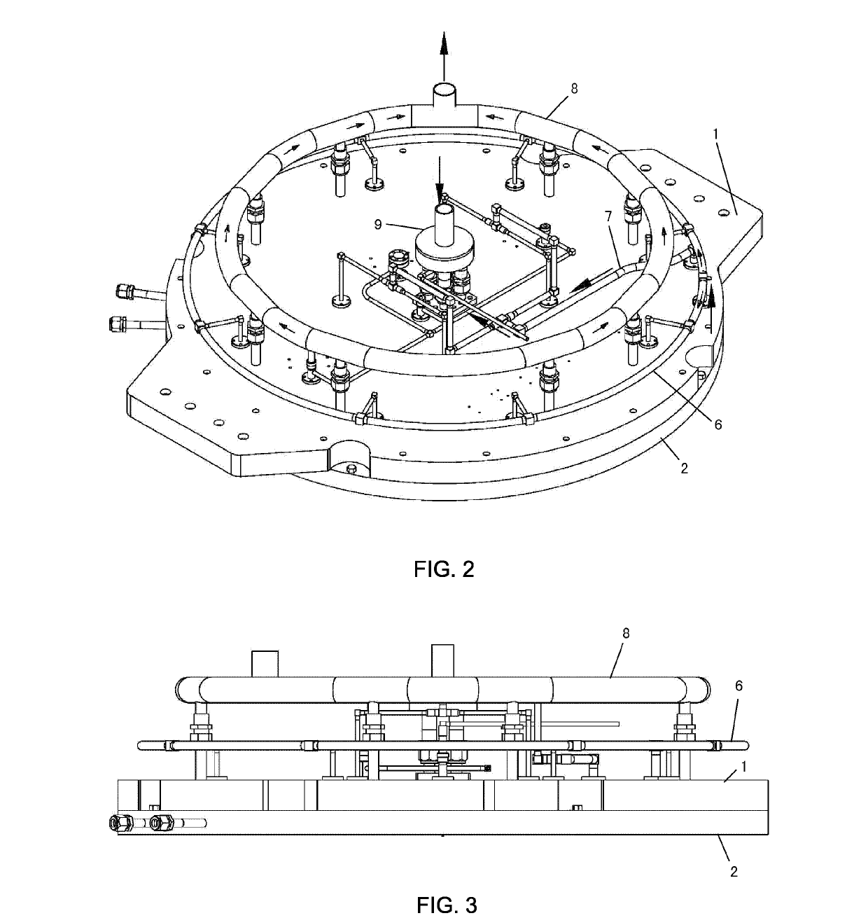

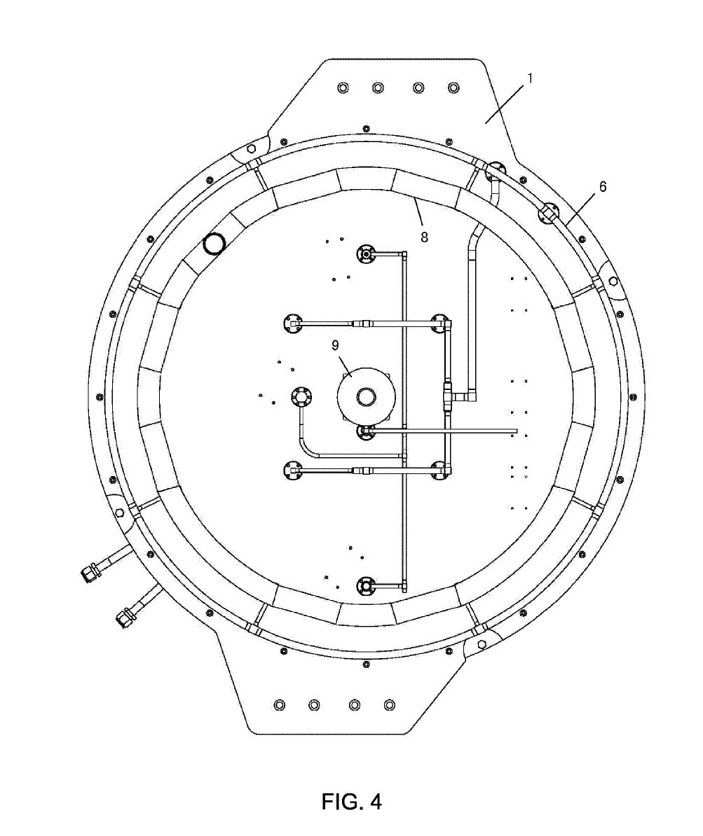

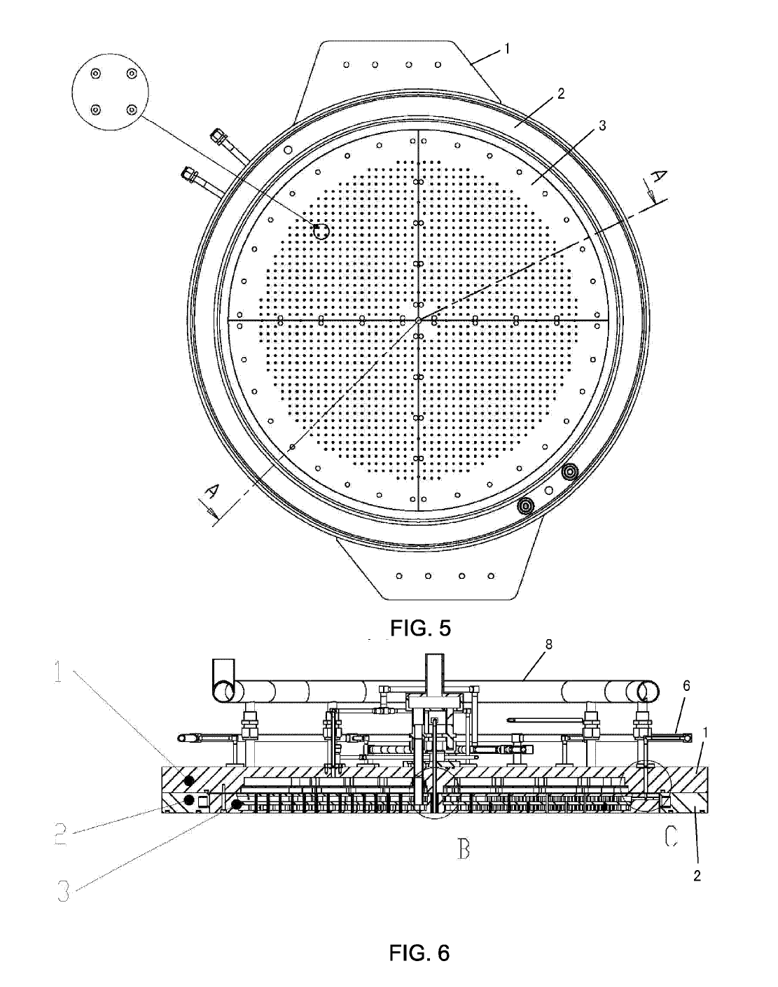

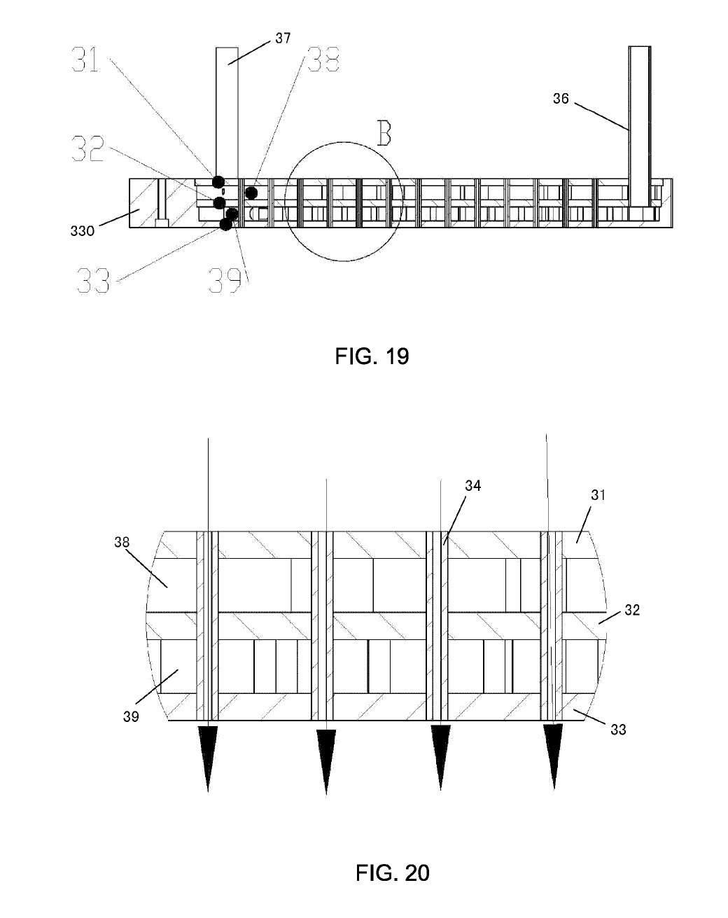

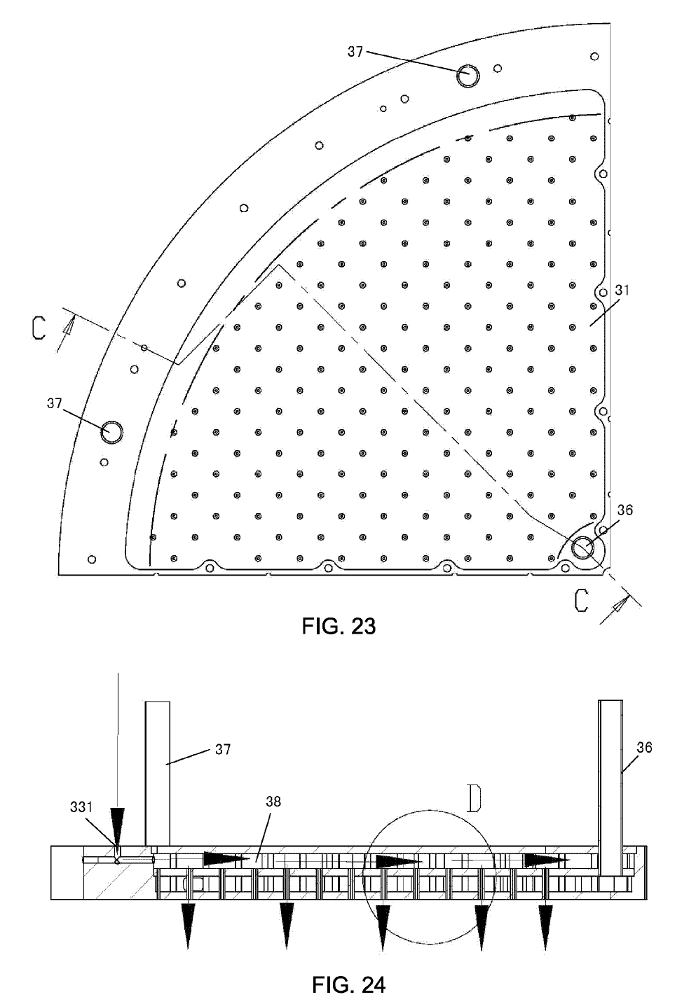

FIGS. 1 through 25 illustrate a showerhead according to one embodiment of the present invention, wherein the showerhead is applicable to a MOCVD reactor with a large diameter.

As shown in FIG. 1, in one embodiment of the present invention, the showerhead includes a top assembly 1, a cooling water ring 2, a showering assembly 3. The top assembly 1, the cooling water ring 2 and the showering assembly 3 are discussed below at the first place, followed by the description of the overall structure of the showerhead.

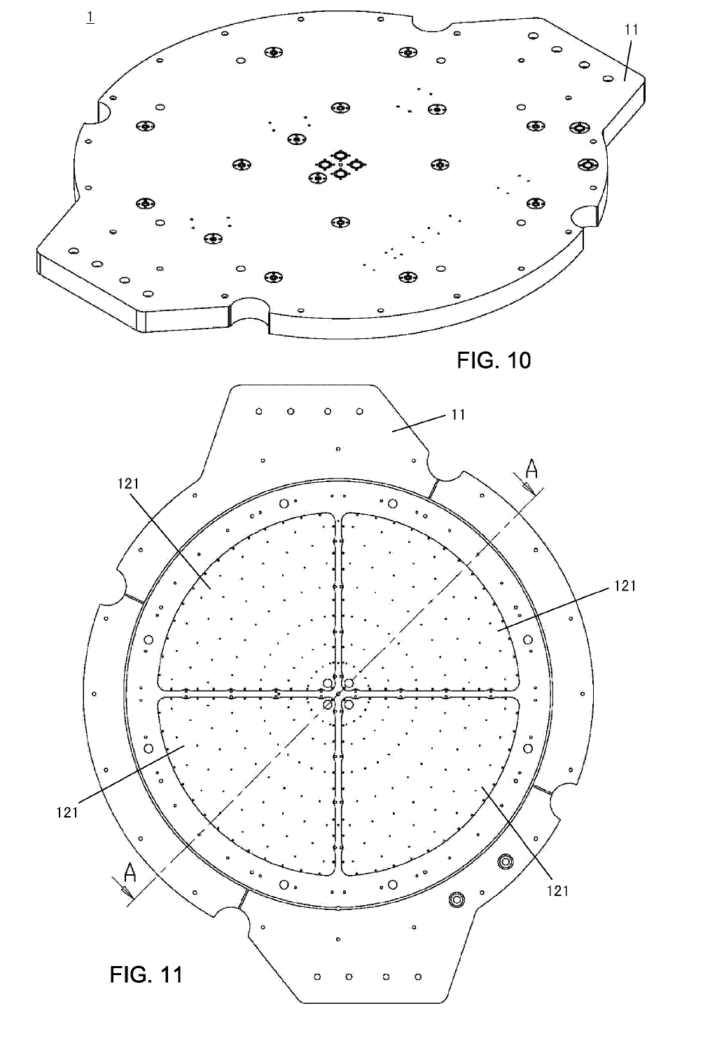

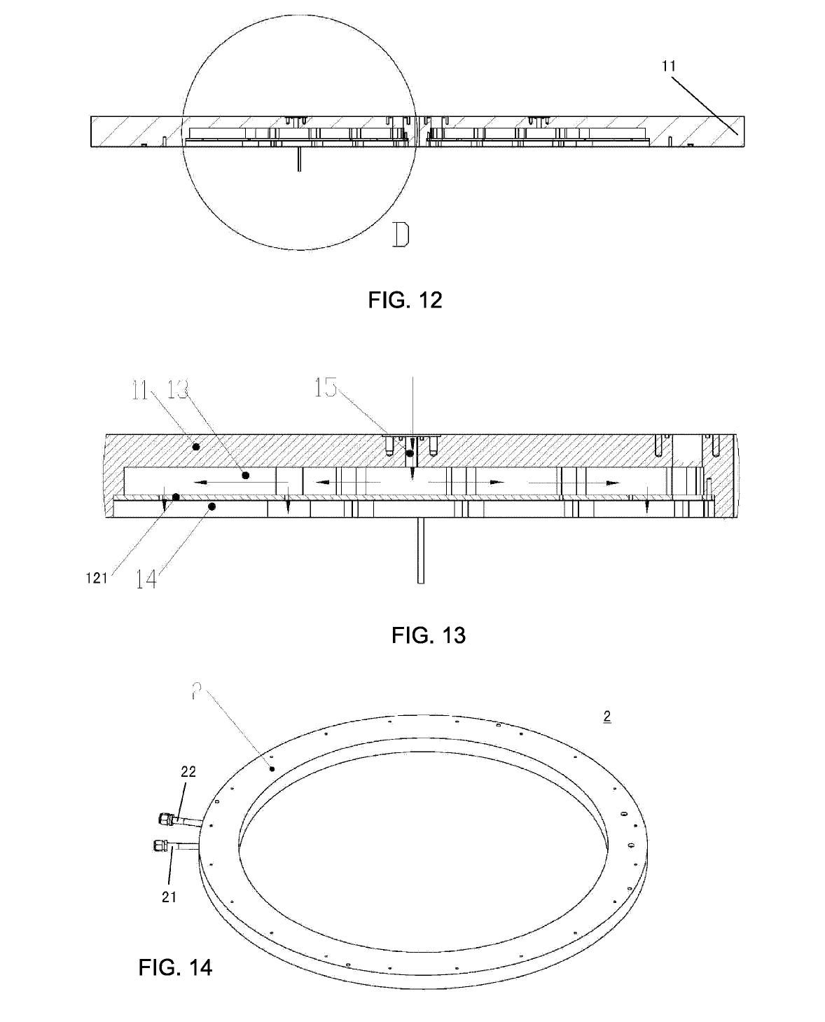

As shown in FIG. 9, FIG. 10 and FIG. 11, the top assembly 1 includes an upper cover plate 11 and a distribution orifice plate 12. The distribution orifice plate 12 can be removably coupled to the upper cover plate 11. The distribution orifice plate 12 includes four equally-divided orifice plates 121. The four orifice plates 121 have the same structures. The below description of one of the orifice plates 121 is also applicable to the other three orifice plates 121. The distribution orifice plate 12 is in a round shape. Each orifice plate 121 can be mounted removably and independently on the upper cover plate 11. As shown in FIG. 12 and FIG. 13, the orifice plate 121 is disposed on a chamber body of the upper cover plate 11 and the orifice plate 121 divides the chamber body into an upper chamber body 13 and a lower chamber body 14. In one embodiment of the present invention, the orifice plate 121 is mounted into a counterbored hole in the upper cover plate 11. The annular sidewall of the counterbored hole is in a stepped shape. The orifice plate 121 is disposed on a shaft shoulder of the sidewall of the counterbored hole, thereby dividing the counterbored hole into the upper chamber body 13 and the lower chamber body 14. In a substantially central position of the upper chamber body 13, the upper cover plate 11 has a group-III gas inlet 15 formed thereon. The group-III gas inlet 15 leads to the upper chamber body 13. The upper chamber body 13 and the lower chamber body 14 are interconnected via the holes in the orifice plate 121. Below the top assembly 1 (i.e., below the distribution orifice plate 12) lies the showering assembly 3. After the group-III gas enters from the upper chamber body 13 into the lower chamber body 14, the group-III gas may be directed to the reaction chamber by the upper capillary group 17. A sealing pad 4 is disposed between the top assembly 1 and the showering assembly 3.

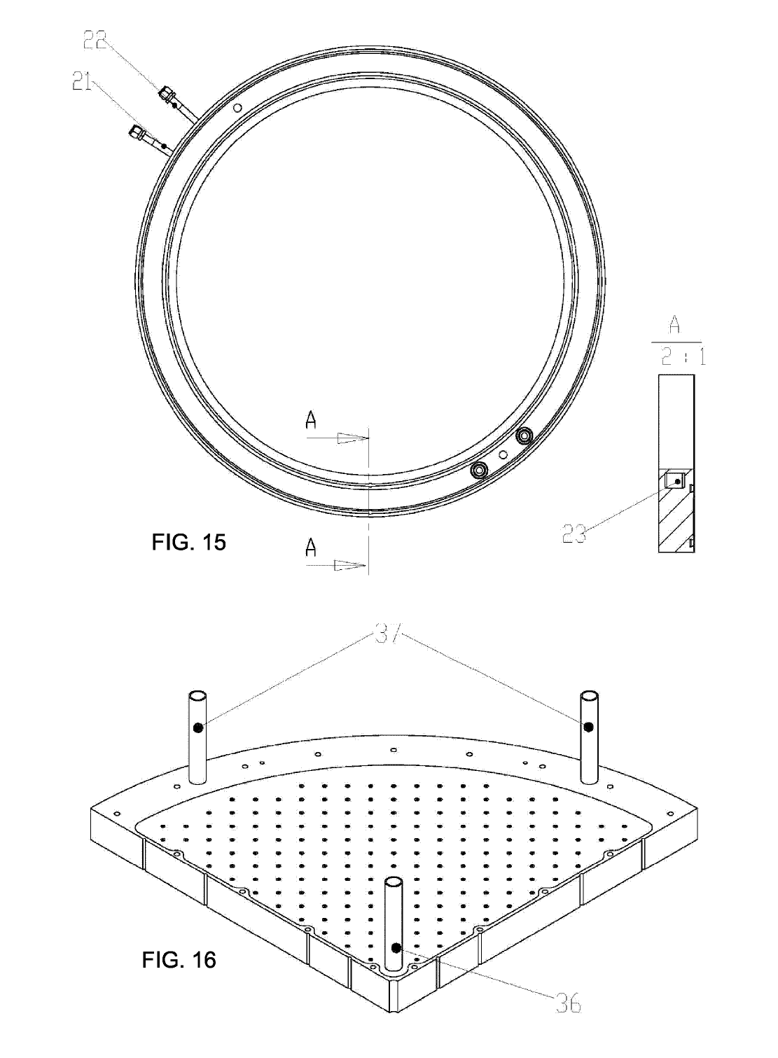

As shown in FIG. 14 and FIG. 15, the cooling water ring 2 has an annular cooling water passage 23. Beside the cooling water passage 23, a cooling water inlet 21 and a cooling water outlet 22 are coupled to the cooling water passage 23. The cooling water starts from the water inlet 21 and flows along the cooling water passage 23 and then comes out of the water outlet 22.

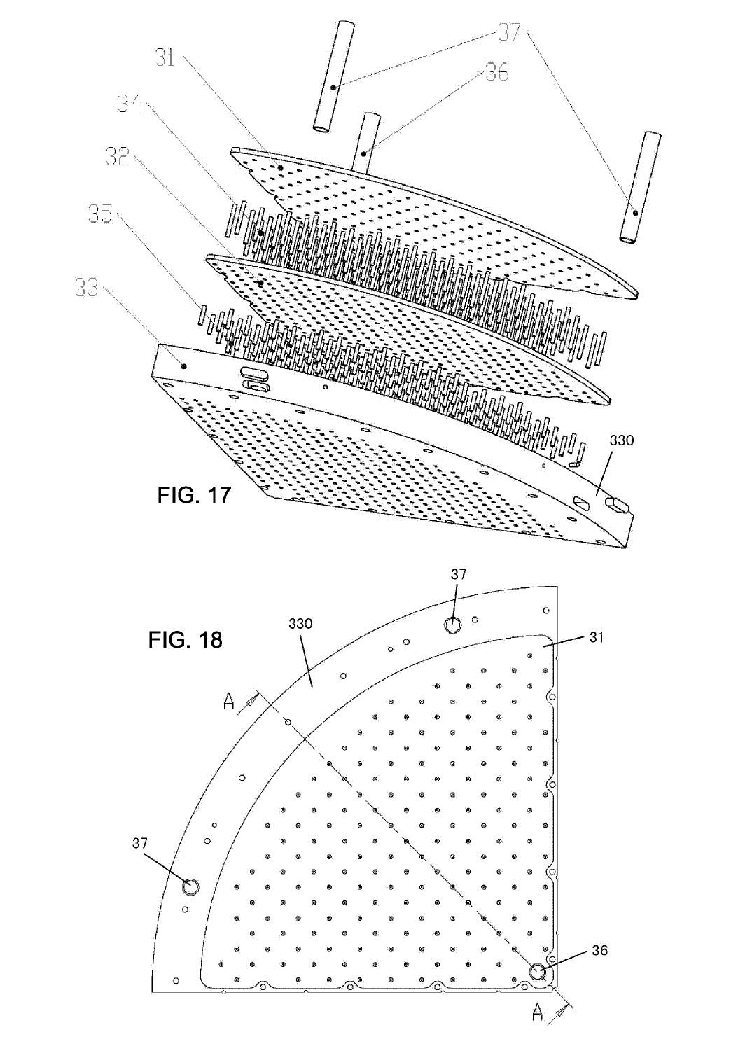

As shown in FIG. 1, the showering assembly 3 consists of four independent showering units. The showering units each have the same structure. Each showering unit is in a right-angled fan shape. The whole showering assembly 3 is in a substantially round shape. As shown in FIG. 16 and FIG. 17, each showering unit of the showering assembly 3 includes an upper orifice plate 31, a middle orifice plate 32, a lower orifice plate 33, an upper capillary group 34, a lower capillary group 35, a water inlet 36 and a water outlet 37.

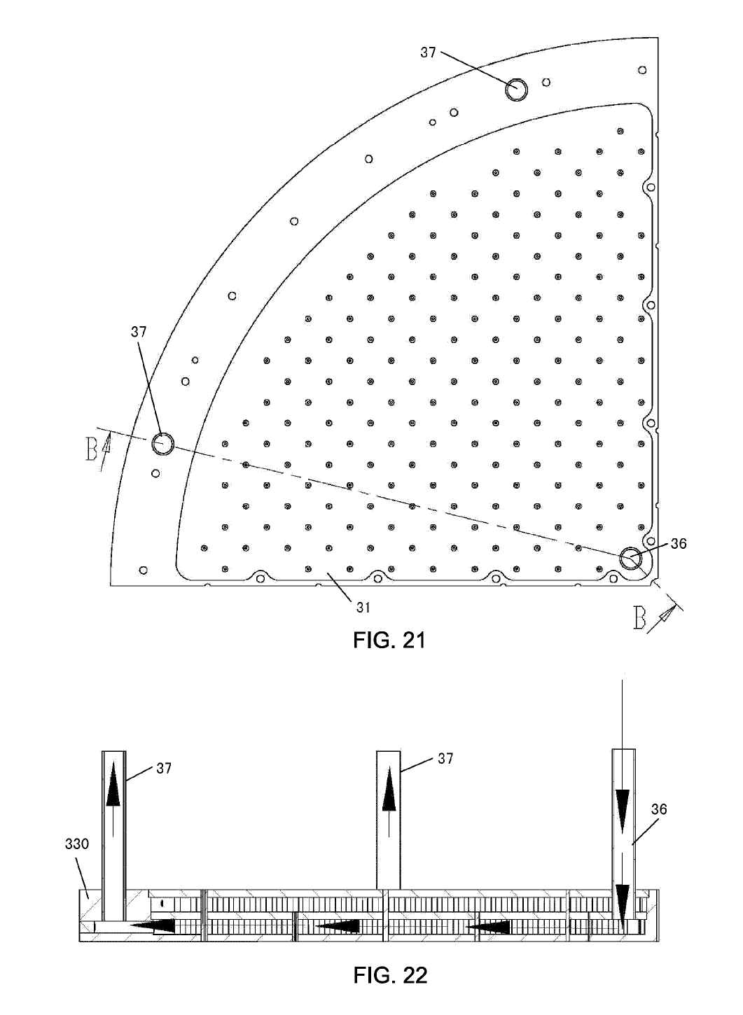

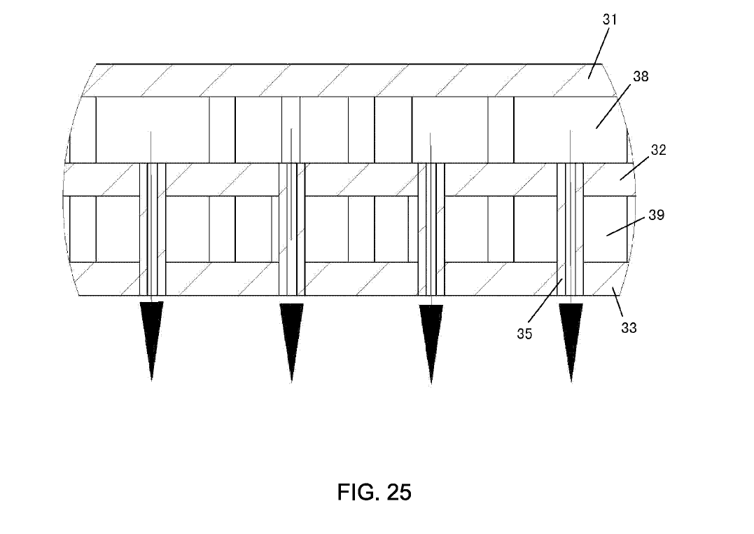

The upper orifice plate 31, the middle orifice plate 32, and an enclosure sidewall between the upper orifice plate 31 and the middle orifice plate 32 consitute a group-V chamber 38 which allows the group-V gas to flow inside. The middle orifice plate 32, the lower orifice plate 33, and an enclosure sidewall between the middle orifice plate 32 and the lower orifice plate 33 constitute a cooling water chamber 39. In one embodiment of the present invention, the enclosure sidewall 330 as a whole extends upwards from the upper orifice plate 33. The upper orifice plate 31 and the middle orifice plate 32 are disposed on the shaft shoulder of the enclosure sidewall, respectively. As shown in FIG. 20, capillaries in the upper capillary group 34 are disposed through the holes in the upper orifice plate 31, the middle orifice plate 32 and the lower orifice plate 33, so that the group-III gas above the upper orifice plate 31 is directed immediately to the reaction chamber below the lower orifice plate 33. As shown in FIG. 25, capillaries in the lower capillary group 35 are disposed through the holes in the middle orifice plate 32 and the lower orifice plate 33, so that the gas inside the group-V chamber 38 is directed to the reaction chamber below the lower orifice plate 33. The group-V chamber 38 and the cooling water chamber 39 cannot be communicated with each other. The cooling water chamber 39 and the reaction chamber below the lower orifice plate 33 cannot be communicated with each other, neither. As shown in FIG. 21 and FIG. 22, the cooling water inlet 36 is disposed in the vertex of the fan-shaped showering unit, which leads to the vertex of the fans in the cooling water chamber 39. The two water outlets 37 are spaced apart on the circumference of the showering unit, which leads to the circumferential direction of the cooling water chamber 39. The water inlet 36 and the cooling water chamber 39 are both disposed vertically on the enclosure sidewall 330.

The arrow shown in FIG. 22 indicates the flow path of the cooling water for the showering assembly 3. The cooling water enters the distribution conduit 9 from an external cooling water pipe (as shown in FIG. 1). The distribution conduit 9 is coupled to the water inlet of each showering unit and distributes evenly to the four showering units. The cooling water first enters from the water inlet 36, and flows towards the circumferential direction of the cooling water chamber 39 starting from the vertex of the fans in the cooling water chamber 39 and then exits from the water outlet 37 on the circumference. Compared with the solution where the cooling water enters from the circumference, since the cooling water enters from the center and exits at the circumference, the foregoing embodiment halves the flow path of the cooling water, thereby improving the cooling effect.

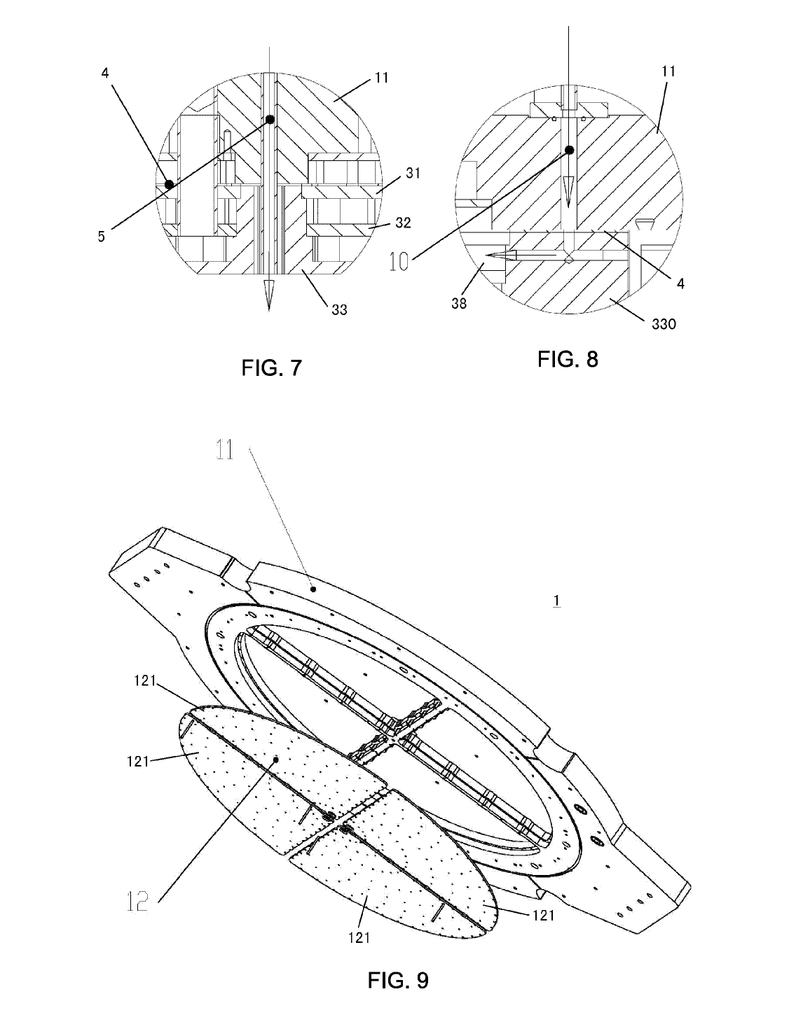

The arrow shown in FIG. 24 indicates the flow path of the group-V gas. The group-V gas inlet 331 of the showering assembly 3 is disposed on the enclosure sidewall 330. That is, the group-V gas inlet 331 of the showering assembly 3 is disposed on the circumference of the group-V chamber 38. The group-V gas inlet 331 leads to the group-V chamber 38. The group-V gas enters the upper cover plate 11 of the top assembly 1 and the passage 10 (as shown in FIG. 6 and FIG. 8) along the circumference of the lower orifice plate 33 via the group-V gas conduit 6 (as shown in FIG. 1). The group-V gas enters along the circumferential direction and fills the group-V chamber 38, and then enters the reaction chamber body via the lower capillary group 35. In addition, as shown in FIG. 6 and FIG. 7, in the middle of the showerhead, a current of the group-V gas enters the reaction chamber body through a central group-V gas conduit 5 in the middle.

As illustrated in FIGS. 1 through 6, the central group-V gas conduit 5, a group-III gas conduit 7, a cooling water distribution conduit 9 and a circumferential V-group gas conduit 6 are disposed above the top assembly 1. The cooling water ring 2 and the showering assembly 3 are disposed below the top assembly 1. The showering assembly 3 is disposed in the cooling water ring 2. The sealing pad 4 is disposed between the showering assembly 3 and the top assembly 1. The circumferential V-group gas conduit 6 provides group-V gas for the group-V gas chamber of the showering assembly 3. The central V-group gas conduit 5 provides group-V gas for the reaction chamber along the center of the entire showerhead.

When the showerhead operates, the group-III gas enters from the group-III gas conduit 7 to each upper chamber body 13 of the top assembly 1. The group-III gas enters from the upper chamber body 13 to the lower chamber body 14 through the holes in the orifice plate 121, and then enters from the lower chamber body 14 to the reaction chamber through the upper capillary group 34. The outlet of the upper capillary group 34 is distributed above the reaction chamber. At the same time, the group-V gas enters the central group-V gas conduit 5 and the circumferential V-group gas conduit 6. The group-V gas enters from the central group-V gas conduit 5 to the group-V chamber 38 of the showering assembly, and then enters from the group-V chamber 38 to the reaction chamber through the lower capillary group 35. The outlets of the lower capillary group 35 are distributed above the reaction chamber and are interleaved with the outlets of the upper capillary group 34, which facilitates a uniform mixing of the group-III gas and group-V gas. Meanwhile, the group-V gas reaches the reaction chamber directly from the center of the entire showerhead. Thus, the concentration distribution of the group-V gas is improved and the flowing status of the gas is enhanced. It is to be noted that the holes in the distribution orifice plate 12 of the top assembly 1 are distributed unevenly. For instance, the nearer to the group-III gas inlet 15, the lower the concentration of the holes will be, while the farther from the group-III gas inlet 15, the higher the concentration of the holes will get. As such, the group-III chamber is divided into an upper chamber and a lower chamber by the distraction orifice plate. And, the varient arrangement of the holes in the distribution orifice plate facilitates the concentration distribution of the group-III along the radial direction. In one aspect, the showering assembly 3 is cooled by the cooling water entering the distribution conduit 9. In other aspect, the showering assembly 3 can be cooled by the cooling water ring 2. The cooling water of the distribution conduit 9 is evenly divided into four quarters, each of which enters the cooling water inlet 36 of each showering unit, and then enters the cooling chamber 39 of the showering unit. The cooling water flows from the center of the showering unit towards the circumference so as to cool the showering unit all around. Then, the cooling water flows out of the cooling water outlet 37 and further converges at the annular water pipe 8 before flowing out of the entire showerhead. Compared with other solutions where the water enters from the circumference and exits at the circumference, since the cooling water enters from the center of the showering assembly and exits at the circumference, the flow path of the cooling water is halved, which improves the cooling effect thereby increasing the yield rate of the MOCVD reactor having large diameter.

It is to be further noted that in the foregoing embodiment, in the showerhead, the showering unit of the showering assembly as well as the distribution orifice plate of the top assembly consists of equally divided portions, e.g., four equally divided portions. This greatly reduces the manufacturing area of a single piece. Therefore, even if in the case of the MOCVD reactor with a large diameter there will not be a remarkable increase in the complexity in the fabrication and manufacturing of the showerhead. Moreover, the cooling process is also conducted on the four equally divided portions. The cooling of the showerhead is no big issue. Just because the process is conducted on the equally divided four portions, the group-III gas and the group-V gas can be mixed uniformly. Moreover, the inner diameter of the holes and the distance between the holes in each orifice plate can be properly increased so that the difficulty in fabrication and manufacturing is reduced and the yield rate is increased.

Although the present invention is described in accordance with the present embodiments, those skilled in the art are readily appreciated that the foregoing embodiments are for illustration only. Any variations or modifications can be made without departing from the spirit and scope of the present invention. For instance, in the foregoing embodiments, although each orifice plate is equally divided into four portions, the present invention is not so limited. Based on the actual situation, each orifice plate can be divided into no less than two equal portions. Therefore, any variations and modifications made to the foregoing embodiments within the spirit of the present invention shall be construed as one within the scope of appended claims.

What is claimed is:

1. A showerhead of a MOCVD reactor with a large diameter, comprising a group-III chamber, a group-V chamber and a cooling water chamber, characterized in that, the group-III chamber, the group-V chamber and the cooling water chamber each is divided into N chamber bodies, wherein N is a natural number greater than or equal to 2, and each chamber body is an independent chamber body.

2. The showerhead of claim 1, characterized in that, a water inlet member in each chamber body of the cooling water chamber is disposed in an inner center of each chamber body and a water outlet member is disposed at the circumference of each chamber body.

3. The showerhead of claim 1, characterized in that, a group-V gas conduit to a reaction chamber below the showerhead is provided in the middle of the showerhead.

4. The showerhead of claim 1, characterized in that, each chamber body in the group-III chamber is divided into an upper chamber and a lower chamber by a distribution orifice plate, and the upper chamber and the lower chamber are interconnected with each other via the holes on the distribution orifice plate.

5. The showerhead of claim 1, characterized in that, the N chambers are four equally divided chamber bodies.

6. The showerhead of claim 1, characterized in that, the group-III chamber, the group-V chamber and the cooling water chamber are in a round shape; and each chamber body of the group-III chamber, the group-V chamber and the cooling water chamber are in a fan shape.

7. The showerhead of claim 4, characterized in comprising a top assembly and a showering assembly, wherein the top assembly comprises an upper cover plate for providing the group-III chamber; a group-III gas inlet is formed on the upper cover plate; the group-III gas inlet is interconnected with the upper chamber of the group-III chamber; and wherein the showering assembly comprises N showering units, each showering unit comprises an upper orifice plate, a middle orifice plate, a lower orifice plate, an enclosure sidewall, an upper capillary group and a lower capillary group; the upper orifice plate, the middle orifice plate and the enclosure sidewall between the upper orifice plate and the middle orifice plate form a chamber body of the group-V chamber; the group-V gas inlet leading to the chamber body of the group-V chamber is formed on the enclosure sidewall; the middle orifice plate, the lower orifice plate and the enclosure between the middle orifice plate and the lower orifice plate form a chamber body of the cooling water chamber; capillaries in the upper capillary group are disposed through holes in the upper orifice plate, the middle orifice plate and the lower orifice plate; capillaries in the lower capillary group are disposed through holes in the middle orifice plate and the lower orifice plate; the group-V chamber and the cooling water chamber cannot be communicated with each other, the lower capillary group links the group-V chamber with the reaction chamber below the showerhead; the showering assembly is disposed below the top assembly and each capillary of the upper capillary group links the group-III chamber with the reaction chamber below the showerhead; the upper capillary group and the lower capillary group are positioned in an interleaving manner.

8. The showerhead of claim 7, characterized in that, the external of the showering assembly is surrounded with a cooling water ring.

9. The showerhead of claim 7, characterized in further comprising a distribution conduit for distributing cooling water, wherein a water inlet member in each chamber body of the cooling water chamber is disposed in an inner center of each chamber body and a water outlet member is disposed at the circumference of each chamber body; each water inlet member is coupled to the same distribution conduit through a water inlet.
